(19) United States
(12) Patent Application Publication
(10) Pub. No.: US 2025/0107237 A1
(43) Pub. Date: Mar. 27, 2025

(54) ELECTRONIC DEVICE AND MANUFACTURING METHOD OF ELECTRONIC DEVICE

(71) Applicant: InnoLux Corporation, Miao-Li County (TW)

(72) Inventors: Chia-Hao TSAI, Miao-Li county (TW); Ming-Jou Tai, Miao-Li County (TW)

(73) Assignee: InnoLux Corporation, Miao-Li County (TW)

(21) Appl. No.: 18/813,003

(22) Filed: Aug. 22, 2024

(30) Foreign Application Priority Data
Sep. 27, 2023 (CN) 202311255557.5

(51) Int. Cl. H01L 27/12; G02B 5/20

(52) U.S. Cl. CPC H10D 86/60; H10D 86/0231; H10D 86/451; G02B 5/201; H10D 86/441

(57) ABSTRACT

An electronic device including a substrate, a circuit layer, a light filtering layer, an organic insulating layer and a transparent conductive layer is provided by the present disclosure. The circuit layer is disposed on the substrate. The light filtering layer is disposed on the circuit layer and has a first via. The organic insulating layer is disposed on the light filtering layer and has a second via, wherein the second via is corresponding to the first via. The transparent conductive layer is electrically connected to the circuit layer through the first via and the second via. The first via has a first sidewall, the second via has a second sidewall, the first sidewall and the second sidewall are not continuous, and a width of the first via is less than a width of the second via.

### BACKGROUND OF THE DISCLOSURE

### 1. Field of the Disclosure

The present disclosure relates to an electronic device and a manufacturing method of the electronic device, and more particularly to an electronic device including a light filtering layer and a manufacturing method of the electronic device.

### 2. Description of the Prior Art

In current display devices, since color mixing of light will occur when the light passes through the interface area of the light filtering layer and enters the user's eyes at a large viewing angle, a light shielding structure (such as a black matrix layer) is disposed in the interface area of the light filtering layer to prevent the mixed-color light from being observed by the user. However, the aperture ratio of the pixels may thereby be reduced, and the display quality may be affected. Therefore, to increase the aperture ratio or improve the display quality of the display device is still an important issue in the present field.

### SUMMARY OF THE DISCLOSURE

The present disclosure aims at providing an electronic device and a manufacturing method of the electronic device.

An electronic device including a substrate, a circuit layer, a light filtering layer, an organic insulating layer and a transparent conductive layer is provided by the present disclosure. The circuit layer is disposed on the substrate. The light filtering layer is disposed on the circuit layer and has a first via. The organic insulating layer is disposed on the light filtering layer and has a second via, wherein the second via is corresponding to the first via. The transparent conductive layer is electrically connected to the circuit layer through the first via and the second via. The first via has a first sidewall, the second via has a second sidewall, the first sidewall and the second sidewall are not continuous, and a width of the first via is less than a width of the second via.

A manufacturing method of an electronic device is provided by the present disclosure, which includes providing a substrate, forming a circuit layer on the substrate, forming a light filtering layer on the circuit layer, forming an organic insulating layer on the light filtering layer, forming a first via in the organic insulating layer, forming a second via in the light filtering layer, wherein the second via is corresponding to the first via, and forming a transparent conductive layer electrically connected to the circuit layer through the first via and the second via. The first via has a first sidewall, the second via has a second sidewall, the first sidewall and the second sidewall are not continuous, and a width of the second via is less than a width of the first via.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a partial cross-sectional view of an electronic device according to a first embodiment of the present disclosure.

FIG. 2 schematically illustrates a partial top view of a driving element of the electronic device according to the first embodiment of the present disclosure.

FIG. 3 schematically illustrates a top view of a light filtering layer according to a variant embodiment of the first embodiment of the present disclosure.

FIG. 4 schematically illustrates a top view of a light filtering layer according to another variant embodiment of the first embodiment of the present disclosure.

FIG. 5 schematically illustrates a top view of a light filtering layer according to yet another variant embodiment of the first embodiment of the present disclosure.

FIG. 6 schematically illustrates a partial cross-sectional view of the electronic device according to a first embodiment of the present disclosure.

FIG. 7 schematically illustrates a partial top view of a driving element of an electronic device according to a second embodiment of the present disclosure.

FIG. 8 shows a flow chart of a manufacturing method of an electronic device according to a third embodiment of the present disclosure.

FIG. 9, FIG. 10 and FIG. 11 schematically illustrate the manufacturing process of the electronic device according to the third embodiment of the present disclosure.

### DETAILED DESCRIPTION

The present disclosure may be understood by reference to the following detailed description, taken in conjunction with the drawings as described below. It is noted that, for purposes of illustrative clarity and being easily understood by the readers, various drawings of this disclosure show a portion of the device, and certain elements in various drawings may not be drawn to scale.

In addition, the number and dimension of each element shown in drawings are only illustrative and are not intended to limit the scope of the present disclosure.

Certain terms are used throughout the description and following claims to refer to particular elements. As one skilled in the art will understand, electronic equipment manufacturers may refer to an element by different names. This document does not intend to distinguish between elements that differ in name but not function.

In the following description and in the claims, the terms “include”, “comprise” and “have” are used in an open-ended fashion, and thus should be interpreted to mean “include, but not limited to . . . ”.

It will be understood that when an element or layer is referred to as being “disposed on” or “connected to” another element or layer, it can be directly on or directly connected to the other element or layer, or intervening elements or layers may be presented (indirectly). In contrast, when an element is referred to as being “directly on” or “directly connected to” another element or layer, there are no intervening elements or layers presented. When an element or a layer is referred to as being “electrically connected” to another element or layer, it can be a direct electrical connection or an indirect electrical connection. The electrical connection or coupling described in the present disclosure may refer to a direct connection or an indirect connection. In the case of a direct connection, the ends of the elements on two circuits are directly connected or connected to each other by a conductor segment. In the case of an indirect connection, switches, diodes, capacitors, inductors, resistors, other suitable elements or combinations of the above elements may be included between the ends of the elements on two circuits, but not limited thereto.

Although terms such as first, second, third, etc., may be used to describe diverse constituent elements, such constituent elements are not limited by the terms. The terms are used only to discriminate a constituent element from other constituent elements in the specification. The claims may not use the same terms, but instead may use the terms first, second, third, etc. with respect to the order in which an element is claimed. Accordingly, in the following description, a first constituent element may be a second constituent element in a claim.

According to the present disclosure, the thickness, length and width may be measured through optical microscope, and the thickness or width may be measured through the cross-sectional view in the electron microscope, but not limited thereto.

In addition, any two values or directions used for comparison may have certain errors. In addition, the terms “equal to”, “equal”, “the same”, “approximately” or “substantially” are generally interpreted as being within ±20%, ±10%, ±5%, ±3%, ±2%, ±1%, or ±0.5% of the given value.

In addition, the terms “the given range is from a first value to a second value” or “the given range is located between a first value and a second value” represents that the given range includes the first value, the second value and other values there between.

If a first direction is said to be perpendicular to a second direction, the included angle between the first direction and the second direction may be located between 80 to 100 degrees. If a first direction is said to be parallel to a second direction, the included angle between the first direction and the second direction may be located between 0 to 10 degrees.

Unless it is additionally defined, all terms (including technical and scientific terms) used herein have the same meaning as commonly understood by those ordinary skilled in the art. It can be understood that these terms that are defined in commonly used dictionaries should be interpreted as having meanings consistent with the relevant art and the background or content of the present disclosure, and should not be interpreted in an idealized or overly formal manner, unless it is specifically defined in the embodiments of the present disclosure.

It should be noted that the technical features in different embodiments described in the following can be replaced, recombined, or mixed with one another to constitute another embodiment without departing from the spirit of the present disclosure.

The electronic device of the present disclosure may include a package device, a display device, a sensing device, a back-light device, an antenna device, a tiled device, a power source management device, a wearable device (for example, augmented reality device or virtual reality device), other suitable electronic devices or any suitable device applied to the above-mentioned devices, but not limited thereto. The electronic device may be a foldable electronic device, a flexible electronic device or a stretchable electronic device. The display device may include a non-self-emissive display device or a self-emissive display device. The non-self-emissive display device for example includes a liquid crystal display device, but not limited thereto. The self-emissive display device for example includes a light emitting diode display device, but not limited thereto. The display device may for example be applied to laptops, common displays, tiled displays, vehicle displays, touch displays, televisions, monitors, smart phones, tablets, light source modules, lighting devices or electronic devices applied to the products mentioned above, but not limited thereto. The sensing device may include a biosensor, a touch sensor, a fingerprint sensor, other suitable sensors or combinations of the above-mentioned sensors. The antenna device may for example include a liquid crystal antenna device or a non-liquid crystal antenna device, but not limited thereto. The tiled device may for example include a tiled display device or a tiled antenna device, but not limited thereto. The outline of the electronic device may be a rectangle, a circle, a polygon, a shape with curved edge or other suitable shapes. The electronic device may include electronic units, wherein the electronic units may include passive elements or active elements, such as capacitor, resistor, inductor, diode, transistor, sensors, and the like. The diode may include a light emitting diode or a photo diode. The light emitting diode may for example include an organic light emitting diode (OLED) or an in-organic light emitting diode. The in-organic light emitting diode may for example include a mini light emitting diode (mini LED), a micro light emitting diode (micro LED) or a quantum dot light emitting diode (QLED), but not limited thereto. It should be noted that the electronic device of the present disclosure may be combinations of the above-mentioned devices, but not limited thereto. The electronic device may include peripheral systems such as driving systems, controlling systems, light source systems to support display devices, antenna devices, wearable devices (such as augmented reality devices or virtual reality devices), vehicle devices (such as windshield of car) or tiled devices.

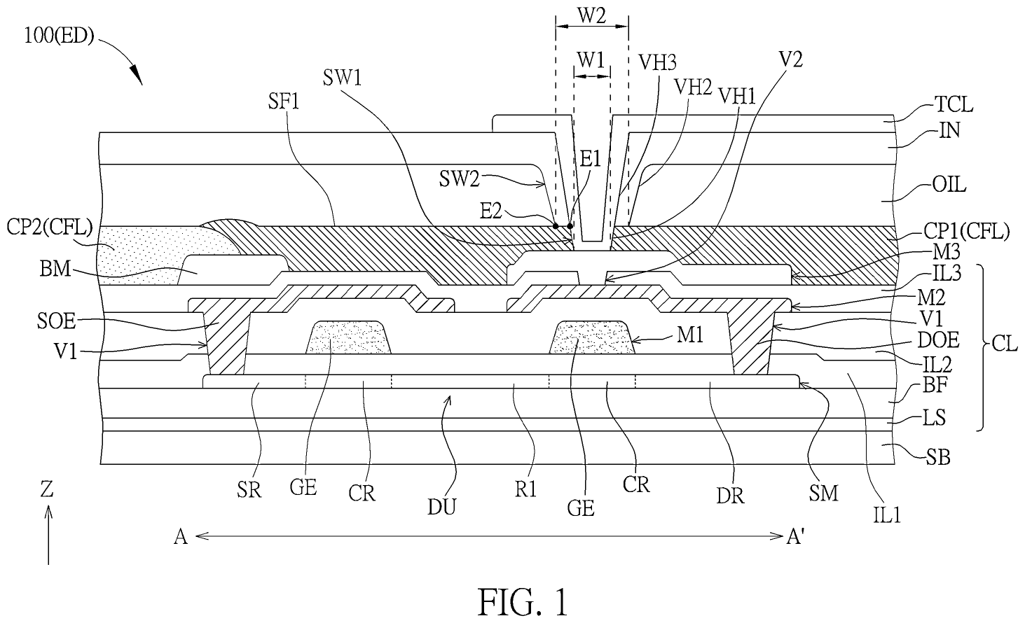

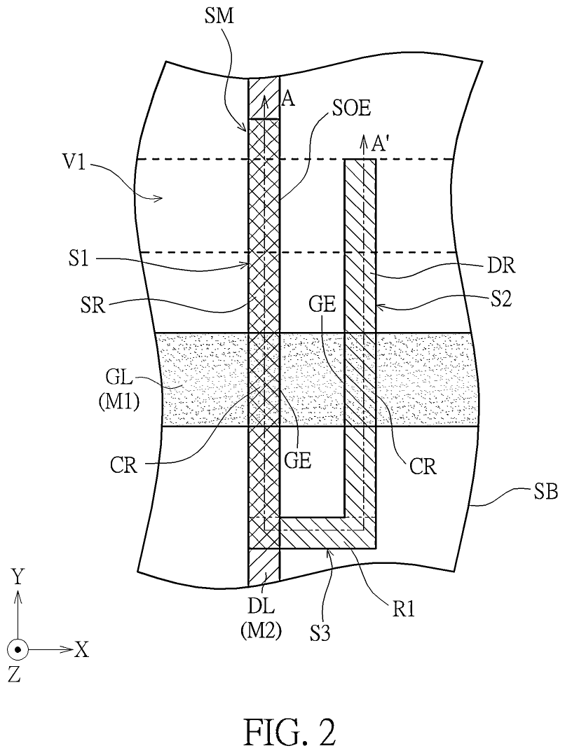

Referring to FIG. 1 and FIG. 2, FIG. 1 schematically illustrates a partial cross-sectional view of an electronic device according to a first embodiment of the present disclosure, and FIG. 2 schematically illustrates a partial top view of a driving element of the electronic device according to the first embodiment of the present disclosure. According to the present embodiment, the electronic device ED may include a substrate SB, a circuit layer CL disposed on the substrate SB, a light filtering layer CFL disposed on the circuit layer CL, an organic insulating layer OIL disposed on the light filtering layer CFL and a transparent conductive layer TCL disposed on the organic insulating layer OIL, but not limited thereto. The electronic device ED of the present embodiment may include a display device 100 for displaying images, but not limited thereto. It should be noted that FIG. 1 just shows a portion of the structure of the electronic device ED, and the electronic device ED may further include other elements and/or layers in addition to the above-mentioned elements and layers. The structures of the elements and the layers of the electronic device ED will be detailed in the following.

The substrate SB may be used to support the elements and the layers disposed thereon. The substrate SB may include rigid material or flexible material. The rigid material for example includes glass, quartz, sapphire, ceramic, other suitable materials or combinations of the above-mentioned materials. The flexible material for example includes polyimide (PI), polycarbonate (PC), polyethylene terephthalate (PET), other suitable materials or combinations of the above-mentioned materials. It should be noted that although the substrate SB shown in FIG. 1 includes a single-layer structure, the present embodiment is not limited thereto. In some embodiments, the substrate SB may include a multi-layer structure.

The circuit layer CL may include various kinds of wires, circuits, electronic units that can be applied to the electronic device ED. The electronic units may include any suitable active element and/or passive element. In the present embodiment, the circuit layer CL may include any suitable structure formed by stacking conductive layers and insulating layers, wherein the conductive layers may be used to form the wires, the circuits or the electronic units mentioned above. For example, as shown in FIG. 1, the circuit layer CL of the present embodiment may include a semiconductor layer SM disposed on the substrate SB, an insulating layer IL1 disposed on the semiconductor layer SM and covering the semiconductor layer SM, a conductive layer M1 disposed on the insulating layer IL1, an insulating layer IL2 disposed on the conductive layer M1 and covering the conductive layer M1, a conductive layer M2 disposed on the insulating layer IL2, an insulating layer IL3 disposed on the conductive layer M2 and covering the conductive layer M2, and a conductive layer M3 disposed on the insulating layer IL3, but not limited thereto. In other embodiments, the circuit layer CL may include any suitable structure according to the design of the electronic device ED.

As shown in FIG. 1, the circuit layer CL of the present embodiment may include driving unit(s) DU. In some embodiments, the circuit layer CL may further include other electronic elements in addition to the driving unit DU, such as switch elements. The driving unit DU may for example include a thin film transistor (TFT) element, but not limited thereto. In the present embodiment, the driving unit DU may include a semiconductor layer SM, a gate electrode GE, a source electrode SOE and a drain electrode DOE, wherein the gate electrode GE may be formed of the conductive layer M1, and the source electrode SOE and the drain electrode DOE may be formed of the conductive layer M2, but not limited thereto. In other words, the driving unit DU may be a top gate TFT. In such condition, the insulating layer IL1 may serve as the gate insulating layer. It should be noted that the structure or the type of the driving unit DU is not limited to what is shown in FIG. 1. In other embodiments, the driving unit DU may include a bottom gate TFT, a dual gate TFT, other suitable elements or combinations of the above-mentioned elements.

Referring to FIG. 2, in order to make the diagram simple and clear, FIG. 2 only shows the substrate SB, the semiconductor layer SM, the conductive layer M1 and the conductive layer M2. As shown in FIG. 2, the electronic device ED may include at least one data line DL and at least one scan line GL disposed on the substrate SB. The scan lines GL may extend along a first direction, and the data lines DL may extend along a second direction, wherein the first direction is not parallel to the second direction. For example, the first direction may be the direction X, and the second direction may be the direction Y, that is, the first direction is perpendicular to the second direction, but not limited thereto. In other embodiments, the first direction may not be perpendicular to the second direction. The gate electrode GE of the driving unit DU may be a portion of the scan line GL, that is, the gate electrode GE is electrically connected to the scan line GL; the source electrode SOE of the driving unit DU may be a portion of the data line DL, that is, the source electrode SOE is electrically connected to the data line DL. Therefore, the scan line GL may be formed of the conductive layer M1, and the data line DL may be formed of the conductive layer M2, but not limited thereto.

In the present embodiment, as shown in FIG. 2, in a top view direction (for example, parallel to the direction Z) of the electronic device ED, the semiconductor layer SM of the driving unit DU may have a U-shaped pattern. The semiconductor layer SM may include a portion S1, a portion S2 and a portion S3 connected between the portion S1 and the portion S2. The portion S1 and the portion S2 are two portions parallel to each other in the U-shaped pattern, and the extending direction of the portion S3 is perpendicular to the extending direction of the portion S1 and the portion S2. In detail, the portion S1 and the portion S2 may extend substantially along a direction parallel to the extending direction of the data line DL (that is, the direction Y). In addition, the data line DL may overlap the portion S1 of the semiconductor layer SM. The portion S3 may extend substantially along a direction parallel to the extending direction of the scan line GL (that is, the direction X). The portion S1 and the portion S2 are connected to the upper side of the portion S3 respectively at two ends of the portion S3. According to the present embodiment, the semiconductor layer SM may include a channel region CR corresponding to the gate electrode GE. Specifically, in the top view direction of the electronic device ED, the scan line GL may extend along the direction X and pass through the portion S1 and the portion S2 of the semiconductor layer SM. In such condition, the portions of the scan line GL overlapping the portion S1 and the portion S2 may respectively be regarded as a gate electrode GE, and the portions of the portion S1 and the portion S2 corresponding to the scan line GL may respectively be regarded as a channel region CR of the semiconductor layer SM. In other words, the driving unit DU of the present embodiment includes two gate electrodes GE, and the semiconductor layer SM of the driving unit DU includes the channel regions CR respectively corresponding to the two gate electrodes GE. The driving unit DU shown in FIG. 2 is the cross-sectional structure of the driving unit DU shown in FIG. 1 along a section line A-A′, and therefore, the structure of the driving unit DU including two gate electrodes GE and two channel regions CR can be observed from FIG. 2. It should be noted that one scan line GL may pass through the semiconductor layers SM of multiple driving units DU at the same time, which is not limited to what is shown in FIG. 2, that is, the circuit layer CL of the electronic device ED may include a plurality of driving units DU. The semiconductor layer SM may further include a source region SR and a drain region DR, wherein the source electrode SOE may be electrically connected to the source region SR, and the drain electrode DOE (not shown in FIG. 2) may be electrically connected to the drain region DR. The source region SR and the drain region DR may be located at two ends of the semiconductor layer SM respectively. The source region SR may for example be located in the portion S1, and the drain region DR may for example be located in the portion S2. Referring to FIG. 1 at the same time, the electronic device ED may include a through hole V1, wherein the through hole V1 may be formed by removing portions of the insulating layer IL1 and the insulating layer IL2, and the through hole V1 may expose the source region SR and the drain region DR of the semiconductor layer SM. In addition, the through hole V1 may extend along the direction X and pass through the portion S1 and the portion S2 of the semiconductor layer SM, that is, the portions of the insulating layer IL1 and the insulating layer IL2 located in the range of the through hole V1 shown in FIG. 2 may be removed to form the through hole V1. The data line DL may be filled into the portion of the through hole V1 overlapping the portion S1 of the semiconductor layer SM and contact the source region SR, thereby forming the source electrode SOE electrically connected to the source region SR. The conductive layer M2 may be filled into the portion of the through hole V1 overlapping the portion S2 of the semiconductor layer SM and contact the drain region DR, thereby forming the drain electrode DOE (not shown in FIG. 2) electrically connected to the drain region DR. It should be noted that the data line DL and the through hole V1 may extend and pass through multiple semiconductor layers SM, which are not limited to what is shown in FIG. 2. In addition, the semiconductor layer SM of the present embodiment may further include a region R1, wherein the region R1 is connected between the two channel regions CR of the semiconductor layer SM. In other words, one of the channel regions CR of the semiconductor layer SM may be connected between the source region SR and the region R1, and the other channel region CR of the semiconductor layer SM may be connected between the drain region DR and the region R1. In the present embodiment, the channel regions CR may be non-doped regions, the source region SR and the drain region DR may be heavily-doped regions, and the region R1 may be a lightly-doped region, but not limited thereto. In a variant embodiment, the region R1 may be a heavily-doped region. In the present embodiment, the material of the semiconductor layer SM may include (but not limited thereto) low temperature poly-silicon (LTPS), amorphous silicon (a-Si), metal oxides (such as indium gallium zinc oxide (IGZO)), other suitable materials or combinations of the above-mentioned materials, and the conductive layers (that is, the conductive layer M1 and the conductive layer M2) forming the gate electrode GE, the source electrode SOE and the drain electrode DOE may include metal materials, but not limited thereto. In other embodiments, the semiconductor layer SM may include other suitable materials according to the demands of the design of the electronic device ED. In addition, the insulating layer IL1, the insulating layer IL2 and the insulating layer IL3 may include any suitable insulating material, such as inorganic insulating material, but not limited thereto.

In some embodiments, the circuit layer CL may optionally include a buffer layer BF disposed on the substrate SB, wherein the buffer layer BF is disposed between the substrate SB and the semiconductor layer SM. The buffer layer BF may include any suitable insulating material. In some embodiments, the circuit layer CL may optionally include a light shielding layer LS, wherein the light shielding layer LS is disposed between the substrate SB and the semiconductor layer SM. When the electronic device ED includes the buffer layer BF, the light shielding layer LS may be disposed between the buffer layer BF and the substrate SB, but not limited thereto. The light shielding layer LS may include any suitable light blocking material, such as metal materials, to reduce the influence of external ambient light on the driving unit DU. The light shielding layer LS may be disposed corresponding to the driving unit DU, or the light shielding layer LS may be disposed corresponding to the semiconductor layer SM (or the channel region CR of the semiconductor layer SM) of the driving unit DU. In some embodiments, the light shielding layer LS may be a patterned layer corresponding to the semiconductor layer SM of the driving unit DU.

According to the present embodiment, the transparent conductive layer TCL may be electrically connected to the driving unit DU, for example, the transparent conductive layer TCL may be electrically connected to the drain electrode DOE of the driving unit DU. In detail, the transparent conductive layer TCL disposed on the organic insulating layer OIL may be electrically connected to the conductive layer M3 of the circuit layer CL through the via VH1 and the via VH2 (the details will be described in the following), and the conductive layer M3 may be electrically connected to the drain electrode DOE through a through hole V2 penetrating the insulating layer IL3. Therefore, the transparent conductive layer TCL may be electrically connected to the driving unit DU. The material of the conductive layer M3 may refer to the material of the conductive layer M1 and the conductive layer M2 mentioned above. In some embodiments, the circuit layer CL may not include the conductive layer M3, and the transparent conductive layer TCL may directly be electrically connected to the drain electrode DOE. In an embodiment, the electronic device ED may include a non-self-emissive display device, and the transparent conductive layer TCL may be the pixel electrode. In such condition, although it is not shown in FIG. 1, the electronic device ED may further include a display medium layer disposed on the transparent conductive layer TCL and a backlight module disposed at a side of the substrate SB opposite to the circuit layer CL, and the driving unit DU may control the display medium layer through the transparent conductive layer TCL to display images. In addition, the electronic device ED may further include an opposite substrate, and the display medium layer may be disposed between the substrate SB and the opposite substrate. The display medium layer for example includes liquid crystal, but not limited thereto. In other embodiments, the driving unit DU may be electrically connected to any suitable electronic unit in the electronic device ED and serve as the driving element according to the design of the electronic device ED.

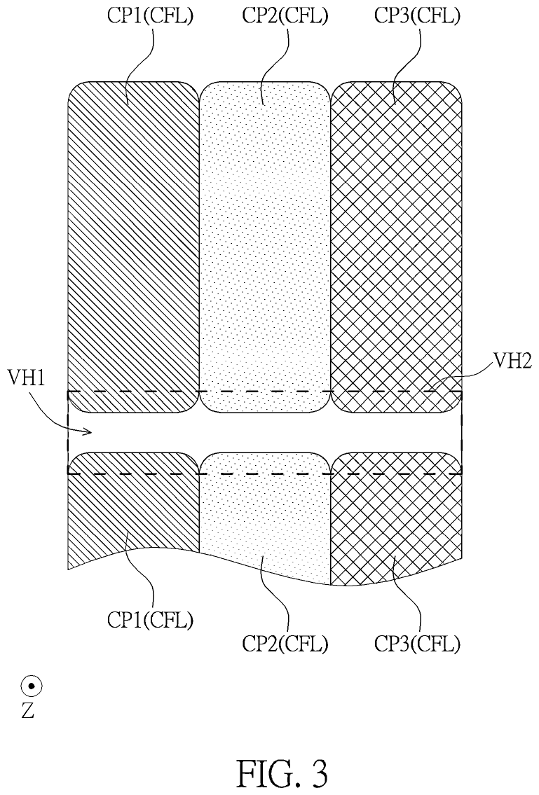

According to the present embodiment, the light filtering layer CFL may directly be disposed on the circuit layer CL. For example, as shown in FIG. 1, the light filtering layer CFL may directly be disposed on the insulating layer IL3 and cover the conductive layer M3. In other words, the electronic device ED of the present embodiment may be formed through a color filter on array (COA) process. The light filtering layer CFL may include any suitable element or layer capable of allowing a light with specific wavelength or color to pass through, such as color filter, but not limited thereto. In the present embodiment, the light filtering layer CFL may include a plurality of light filtering elements, wherein the light filtering elements may respectively allow light of different wavelengths or colors to pass through. For example, as shown in FIG. 3 to FIG. 5, the light filtering layer CFL may include a first light filtering element CP1, a second light filtering element CP2 and a third light filtering element CP3 respectively allowing red light, green light and blue light to pass through, and the light passing through the three light filtering elements may be mixed into a white light, but not limited thereto. In such condition, the first light filtering element CP1, the second light filtering element CP2 and the third light filtering element CP3 may respectively correspond to a sub-pixel, and the three sub-pixels may form a pixel. FIG. 1 exemplarily shows a portion of the first light filtering element CP1 and a portion of the second light filtering element CP2, and the third light filtering element CP3 is not shown in FIG. 1. It should be noted that FIG. 3 to FIG. 5 just exemplarily show a group of the first light filtering element CP1, the second light filtering element CP2 and the third light filtering element CP3, and the electronic device ED may include multiple groups of the first light filtering element CP1, the second light filtering element CP2 and the third light filtering element CP3 disposed on the circuit layer CL, that is, the light filtering layer CFL may be formed of multiple groups of the first light filtering element CP1, the second light filtering element CP2 and the third light filtering element CP3. In addition, the design of the light filtering layer CFL of the present disclosure is not limited to the contents mentioned above, which can be determined according to the demands of the design of the electronic device ED. In some other embodiments, the arrangement of the pixels may include sub-pixel rendering, which is not limited to what is shown in FIG. 3. For example, in the top view direction of the electronic device ED, the light filtering layer CFL above the via VH1 may respectively allow red light, green light and blue light to pass through from left to right (that is, the first light filtering element CP1, the second light filtering element CP2 and the third light filtering element CP3 in order), and the light filtering layer CFL below the via VH1 may respectively allow blue light, red light and green light to pass through from left to right, but not limited thereto.

The electronic device ED of the present embodiment may further include a light shielding layer BM disposed on the circuit layer CL, wherein the light shielding layer BM may be disposed between adjacent light filtering elements. For example, as shown in FIG. 1, the light shielding layer BM may be disposed between the first light filtering element CP1 and the second light filtering element CP2 which are adjacent to each other. Specifically, the light shielding layer BM may have a matrix structure and include a plurality of openings, and the light filtering elements may be disposed corresponding to the plurality of openings of the light shielding layer BM. The light shielding layer BM may include any suitable light shielding material, such as opaque inorganic materials, opaque organic materials, black resin, low-reflective metal materials, metal-molybdenum oxide doped with tantalum (MoOxTa), metal-nitric oxide, or combinations of the above-mentioned materials, but not limited thereto. The low-reflective metal materials may for example include aluminum, molybdenum, titanium, oxides of the above-mentioned materials, nitrides of the above-mentioned materials, molybdenum oxide doped with tantalum, other suitable materials or combinations of at least two of the above-mentioned materials. Through disposition of the light shielding layer BM, the possibility that color mixing of light is observed by the user and thereby affecting the display quality may be reduced.

According to the present embodiment, the light filtering layer CFL may have a via VH1, wherein the via VH1 may be formed by removing a portion of the light filtering layer CFL. The via VH1 may be disposed in the light filtering elements (for example, the first light filtering element CP1, the second light filtering element CP2 and the third light filtering element CP3) of the light filtering layer CFL and may penetrate through the light filtering elements. For example, as shown in FIG. 1, the first light filtering element CP1 of the light filtering layer CFL may have at least one via VH1 penetrating through the first light filtering element CP1 and exposing the conductive layer M3 electrically connected to the drain electrode DOE of the driving unit DU. In other words, at least a portion of the first light filtering element CP1 corresponding to the conductive layer M3 electrically connected to the driving unit DU may be removed to form the via VH1, that is, the disposition position of the via VH1 is corresponding to the position of the conductive layer M3 electrically connected to the driving unit DU. Therefore, the transparent conductive layer TCL disposed on the light filtering layer CFL may extend into the via VH1 and contact the conductive layer M3 to be electrically connected to the driving unit DU. In some embodiments, when the electronic device ED does not include the conductive layer M3, the transparent conductive layer TCL may directly contact the drain electrode DOE of the driving unit DU through the via VH1 (and the through hole V2 mentioned above).

It should be noted that the via VH1 may further be disposed in other light filtering elements of the light filtering layer CFL, which is not limited to be disposed in the first light filtering element CP1. FIG. 1 just exemplarily shows the structure that the first light filtering element CP1 includes the via VH1. For example, each of the light filtering elements of the light filtering layer CFL may include at least one via VH1, but not limited thereto. In such condition, the electronic device ED may include a transparent conductive layer TCL disposed on the second light filtering element CP2 (or the third light filtering element CP3) and a driving unit DU electrically connected to the transparent conductive layer TCL, and the via VH1 in the second light filtering element CP2 (or the third light filtering element CP3) may expose the conductive layer M3 electrically connected to the driving unit DU (for example, the drain electrode DOE), such that the transparent conductive layer TCL may be electrically connected to the driving unit DU through the via VH1.

In the present embodiment, the organic insulating layer OIL may directly be disposed on the light filtering layer CFL and cover the light filtering layer CFL, that is, the organic insulating layer OIL may contact the light filtering layer CFL. Therefore, the organic insulating layer OIL may provide protection to the elements and the layers (such as the driving unit DU) disposed there below. In addition, the organic insulating layer OIL may provide a flat top surface to facilitate the disposition of other elements and layers thereon, such as the transparent conductive layer TCL. The organic insulating layer OIL may include any suitable organic insulating material.

According to the present embodiment, the organic insulating layer OIL may have a via VH2, wherein the via VH2 may be formed by removing a portion of the organic insulating layer OIL. The via VH2 may correspond to the via VH1, that is, the via VH2 may at least partially overlap the via VH1 in the top view direction of the electronic device ED. The via VH2 may be located on the via VH1. For example, the organic insulating layer OIL may have the via VH2 corresponding to the via VH1 of the light filtering layer CFL (for example, the first light filtering element CP1, but not limited thereto). Therefore, the conductive layer M3 electrically connected to the driving unit DU may be exposed by the via VH1 and the via VH2. By making the light filtering layer CFL include the via VH1 and making the organic insulating layer OIL include the via VH2 corresponding to the via VH1, the transparent conductive layer TCL may extend into a via VH1 and a via VH2 corresponding to the via VH1 and contact the conductive layer M3 electrically connected to the driving unit DU.

In other words, the transparent conductive layer TCL may be electrically connected to the circuit layer CL (or the driving unit DU in the circuit layer CL) through the via VH1 and the via VH2. It should be noted that although it is not shown in FIG. 1, the organic insulating layer OIL may include the vias VH2 corresponding to the vias VH1 in other light filtering elements (such as the second light filtering element CP2 and the third light filtering element CP3), that is, the electronic device ED may include a via structure formed of multiple groups of via VH1 and via VH2 which are corresponding to each other.

According to the present embodiment, as shown in FIG. 1, a via VH1 of the light filtering layer CFL (or the first light filtering element CP1 of the light filtering layer CFL) has a sidewall SW1, and the via VH2 of the organic insulating layer OIL corresponding to the via VH1 has a sidewall SW2, wherein the sidewall SW1 and the sidewall SW2 are not continuous. In short, in a group of the via VH1 and the via VH2 which are corresponding to each other, the sidewall of the via VH1 and the sidewall of the via VH2 are not continuous. “The sidewall SW1 and the sidewall SW2 are not continuous” mentioned above may include any suitable condition that the endpoint of the sidewall SW1 adjacent to the sidewall SW2 is not connected to the endpoint of the sidewall SW2 adjacent to the sidewall SW1 in a cross-sectional view of the electronic device ED. Specifically, in a cross-sectional view of the electronic device ED (for example, FIG. 1), the sidewall SW1 may include an endpoint E1 adjacent to the sidewall SW2, and the sidewall SW2 may include an endpoint E2 adjacent to the sidewall SW1, wherein the endpoint E1 is not connected to the endpoint E2, or the endpoint E1 does not coincide with the endpoint E2, or a distance is included between the endpoint E1 and the endpoint E2, wherein the distance is greater than 0. Since the organic insulating layer OIL may directly be disposed on the light filtering layer CFL, the endpoint E1 of the sidewall SW1 and the endpoint E2 of the sidewall SW2 may be located on the top surface SF1 of the light filtering layer CFL. In other words, in the present embodiment, the intersection point of the sidewall SW1 and the top surface SF1 of the light filtering layer CFL (that is, the endpoint E1) does not coincide with the intersection point of the sidewall SW2 and the top surface SF1 of the light filtering layer CFL (that is, the endpoint E2). In an embodiment, when the sidewall SW1 and the sidewall SW2 are planar in a cross-sectional view of the electronic device ED (for example, as shown in FIG. 1), “the sidewall SW1 and the sidewall SW2 are not continuous” mentioned above may also represent that the sidewall SW1 and the sidewall SW2 are not located on the same plane.

Through the size designs of the via VH1 and the via VH2, in a cross-sectional view of the electronic device ED (for example, FIG. 1), the light filtering layer CFL may protrude from the organic insulating layer OIL, or the side surface of the light filtering layer CFL (corresponding to the sidewall SW1) may protrude from the side surface of the organic insulating layer OIL (corresponding to the sidewall SW2), thereby achieving discontinuity between the sidewall SW1 of the via VH1 and the sidewall SW2 of the via VH2, but not limited thereto. In such condition, at least a portion of the top surface SF1 of the light filtering layer CFL may not be covered by the organic insulating layer OIL, that is, the via VH2 may expose at least a portion of the top surface SF1 of the light filtering layer CFL. In addition, as shown in FIG. 1, the sidewall SW1 and the sidewall SW2 may for example form a staircase-shaped sidewall in the present embodiment, but not limited thereto.

According to the present embodiment, the size of the via VH2 may be greater than the size of the via VH1 to which the via VH2 correspond. For example, the width of the via VH2 may be greater than the width of the via VH1. “The width of the via” described herein may be the width of the bottom of the via in a cross-sectional view of the electronic device ED. For example, as shown in FIG. 1, the via VH1 may have a width W1, and the via VH2 corresponding to the via VH1 may have a width W2, wherein the width W2 may be greater than the width W1. In some embodiments, the size of the via may be the area of the via, for example, the projected area of the via on the plane XY, wherein the area of the via VH2 may be greater than the area of the via VH1.

It should be noted that the structural features of the vias are described by taking the via VH1 in the first light filtering element CP1 and the via VH2 corresponding to the via VH1 shown in FIG. 1 as an example, and the structural features of the vias VH1 in other light filtering elements and the vias VH2 corresponding to the vias VH1 may refer to the contents mentioned above, and will not be redundantly described.

As shown in FIG. 1, the electronic device ED of the present embodiment may further include an insulating layer IN disposed between the organic insulating layer OIL and the transparent conductive layer TCL. In detail, the insulating layer IN may be disposed on the organic insulating layer OIL, and the transparent conductive layer TCL may be disposed on the insulating layer IN. According to the present embodiment, the insulating layer IN may be disposed in the via VH2 and disposed on the light filtering layer CFL. Specifically, a portion of the insulating layer IN may enter the via VH2 and extend along the sidewall SW2 of the via VH2, such that the insulating layer IN may contact the top surface SF1 of the light filtering layer CFL, or the insulating layer IN may contact the portion of the top surface SF1 of the light filtering layer CFL exposed by the via VH2. In other words, a portion of the insulating layer IN may directly be disposed on the light filtering layer CFL. In such condition, the insulating layer IN may contact the sidewall SW2 of the via VH2, or the insulating layer IN may cover the side surface of the organic insulating layer OIL (corresponding to the sidewall SW2). The insulating layer IN may include a via VH3, wherein the via VH3 may correspond to the via VH1 and the via VH2. The insulating layer IN may be used to protect the organic insulating layer OIL in the forming process of the via VH1 (which will be described in the following), such that the possibility of damage to the organic insulating layer OIL may be reduced. The insulating layer IN may include any suitable inorganic insulating material, such as silicon nitride (SiNₓ), but not limited thereto.

According to the present embodiment, since the light filtering layer CFL of the electronic device ED may directly be disposed on the circuit layer CL, that is, the electronic device ED is formed through the color filter on array process, the possibility of affecting the display quality of electronic device ED due to color mixing of light may be reduced. In addition, by making the size (for example, the width) of the via VH1 in the light filtering layer CFL less than the size (for example, the width) of the via VH2 in the organic insulating layer OIL to which the via VH1 correspond, that is, making the via VH1 and the via VH2 to which the via VH1 correspond have a discontinuous sidewall, the covering area of the light filtering layer CFL may increase. Therefore, the possibility of light leakage at the via VH1 may be reduced, thereby improving the display quality of the electronic device ED.

Some examples of the present embodiment about the structures of the light filtering layer CFL, the via VH1 and the via VH2 of the electronic device ED will be described in the following.

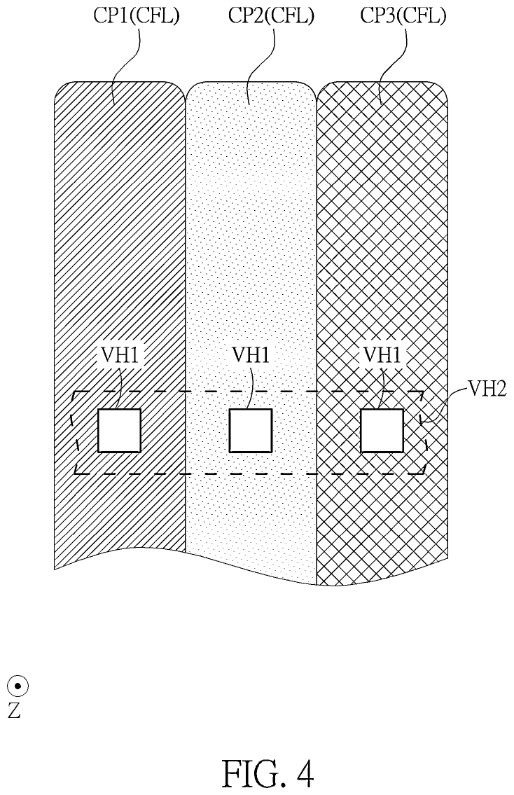

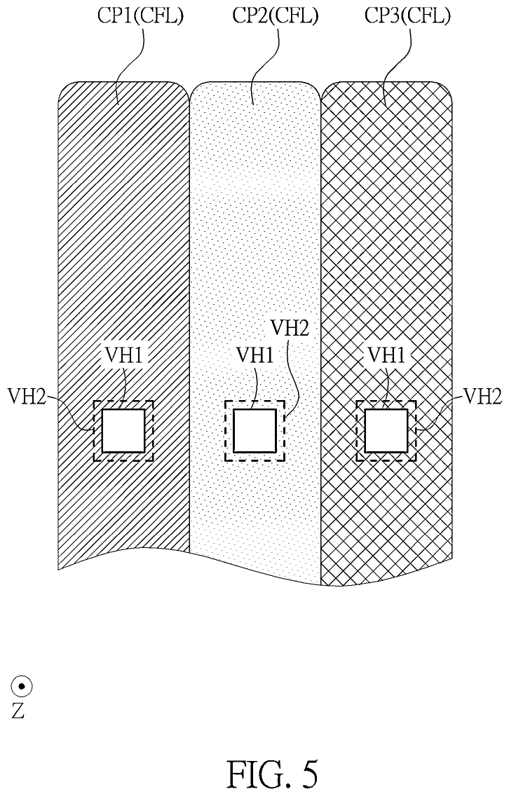

Referring to FIG. 3 to FIG. 5, FIG. 3 schematically illustrates a top view of a light filtering layer according to a variant embodiment of the first embodiment of the present disclosure, FIG. 4 schematically illustrates a top view of a light filtering layer according to another variant embodiment of the first embodiment of the present disclosure, and FIG. 5 schematically illustrates a top view of a light filtering layer according to yet another variant embodiment of the first embodiment of the present disclosure.

According to the present embodiment, the light filtering layer CFL may include a patterned structure, or the light filtering elements of the light filtering layer CFL may be patterned elements.

Specifically, in the forming process of the light filtering layer CFL, a plurality of patterned first light filtering elements CP1, a plurality of patterned second light filtering elements CP2 and a plurality of patterned third light filtering elements CP3 may respectively be formed on the circuit layer CL, thereby forming the light filtering layer CFL. In some embodiments, as shown in FIG. 3, the light filtering layer CFL may include an island-shaped structure, or the first light filtering elements CP1, the second light filtering elements CP2 and the third light filtering elements CP3 of the light filtering layer CFL may be island-shaped. In some embodiments, as shown in FIG. 4 and FIG. 5, the light filtering layer CFL may include a strip-shaped (or string-shaped) structure, or the first light filtering elements CP1, the second light filtering elements CP2 and the third light filtering elements CP3 of the light filtering layer CFL may be strip-shaped (or string-shaped). It should be noted that the light filtering layer CFL may include any suitable patterned structure according to the demands of the design of the electronic device ED, which is not limited to the structures mentioned above.

In addition, FIG. 3 to FIG. 5 show some embodiments about the structures of the via VH1 and the via VH2. In some embodiments, as shown in FIG. 3, a via VH1 in the light filtering layer CFL may be formed by removing portions of the plurality of light filtering elements, and the organic insulating layer OIL may include a via VH2 corresponding to the via VH1. In other words, the vias in the plurality of light filtering elements may be connected to each other and be regarded as a continuous via VH1. For example, the via VH1 may include a continuous structure formed by removing a portion of the first light filtering elements CP1, a portion of the second light filtering elements CP2 and a portion the third light filtering elements CP3 of the light filtering layer CFL, but not limited thereto. The via VH2 may have a slit shape (indicated by a dotted line in FIG. 3) or other suitable strip shapes and may correspond to the via VH1, that is, the via VH2 may overlap the continuous via VH1 in the top view direction of the electronic device ED. In such condition, the via VH2 may expose at least a portion of the first light filtering elements CP1, at least a portion of the second light filtering elements CP2 and at least a portion the third light filtering elements CP3 at the same time. It should be noted that the via VH1 may be formed by removing portions of any number of light filtering elements, which is not limited to what is shown in FIG. 3. In some embodiments, as shown in FIG. 4, the light filtering elements (for example, the first light filtering elements CP1, the second light filtering elements CP2 and the third light filtering elements CP3) of the light filtering layer CFL may respectively include the vias VH1 which are independent to each other, and the organic insulating layer OIL may include a via VH2 having a slit shape or other suitable string shapes, wherein the via VH2 may overlap the plurality of vias VH1 in the top view direction of the electronic device ED. In some embodiments, as shown in FIG. 5, the light filtering elements (for example, the first light filtering elements CP1, the second light filtering elements CP2 and the third light filtering elements CP3) of the light filtering layer CFL may respectively include the vias VH1 which are independent to each other, and the organic insulating layer OIL may include the vias VH2 respectively corresponding to the vias VH1 and independent to each other.

It should be noted that the via VH1 and the via VH2 may include any suitable structure according to the demands of the design of the electronic device ED, which is not limited to the contents mentioned above.

Other embodiments of the present disclosure will be described in the following. In order to simplify the description, the same elements or layers in the following embodiments would be labeled with the same symbol, and the features thereof will not be redundantly described. The differences between the embodiments will be detailed in the following.

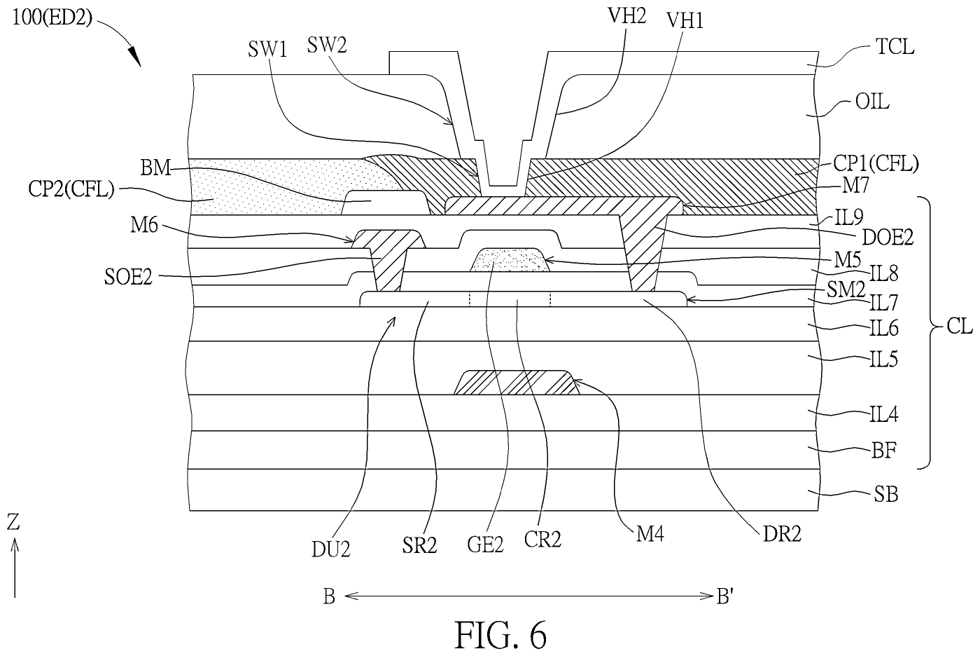

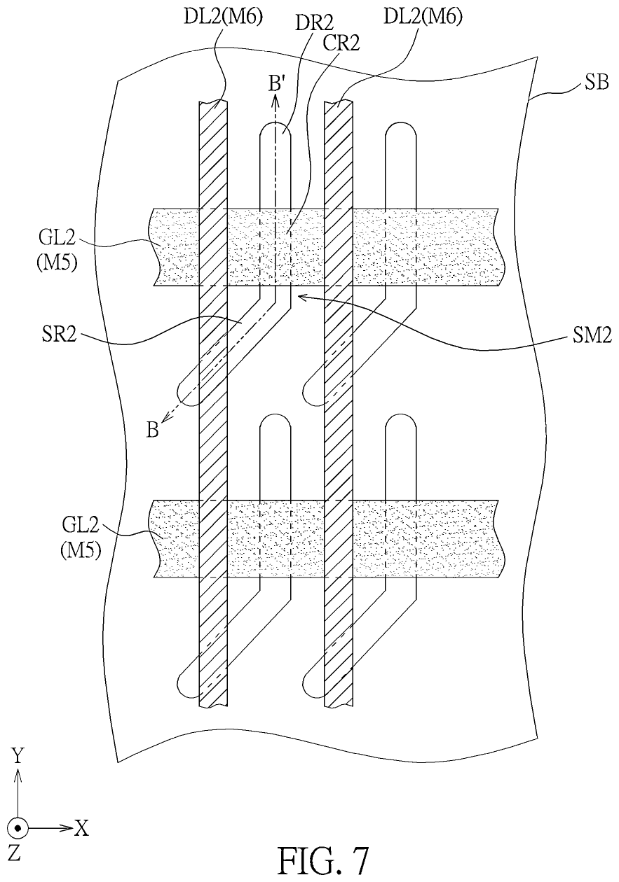

Referring to FIG. 6 and FIG. 7, FIG. 6 schematically illustrates a partial cross-sectional view of the electronic device according to a first embodiment of the present disclosure, and FIG. 7 schematically illustrates a partial top view of a driving element of an electronic device according to a second embodiment of the present disclosure. In order to simplify the figure, FIG. 7 just shows some of the layers of the electronic device. Specifically, the driving unit DU shown in FIG. 6 may be the cross-sectional structure of the structure shown in FIG. 7 along a section line B-B′. One of the differences between the electronic device ED2 of the present embodiment and the electronic device ED of the above-mentioned embodiment is the structural design of the circuit layer CL. In detail, as shown in FIG. 6, the circuit layer CL of the electronic device ED2 may include the buffer layer BF disposed on the substrate SB, an insulating layer IL4 disposed on the buffer layer BF, a conductive layer M4 disposed on the insulating layer IL4, an insulating layer IL5 disposed on the insulating layer IL4 and covering the conductive layer M4, an insulating layer IL6 disposed on the insulating layer IL5, a semiconductor layer SM2 disposed on the insulating layer IL6, an insulating layer IL7 disposed on the insulating layer IL6 and covering the semiconductor layer SM2, a conductive layer M5 disposed on the insulating layer IL7, an insulating layer IL8 disposed on the insulating layer IL7 and covering the conductive layer M5, a conductive layer M6 disposed on the insulating layer IL8, an insulating layer IL9 disposed on the insulating layer IL8 and covering the conductive layer M6, and a conductive layer M7 disposed on the insulating layer IL9, but not limited thereto. The conductive layer M7 may directly contact the light filtering layer CFL and be covered by the light filtering layer CFL. The feature of the buffer layer BF may refer to the contents mentioned above, and will not be redundantly described. The material of the insulating layers of the circuit layer CL may refer to the material of the insulating layer IL1, the insulating layer IL2 and the insulating layer IL3 mentioned above, and will not be redundantly described. It should be noted that the structure of the circuit layer CL mentioned above is exemplary, and the structure of the circuit layer CL of the present embodiment is not limited to what is shown in FIG. 6.

The circuit layer CL of the present embodiment may include driving unit(s) DU2. The driving unit DU2 may include the semiconductor layer SM2, a gate electrode GE2, a source electrode SOE2 and a drain electrode DOE2, wherein the gate electrode GE2 may be formed of the conductive layer M5, the source electrode SOE2 may be formed of the conductive layer M6, and the drain electrode DOE2 may be formed of the conductive layer M7. The semiconductor layer SM2 may include metal oxide semiconductor materials, such as indium gallium zinc oxide, but not limited thereto. The source electrode SOE2 and the gate electrode GE2 may include any suitable conductive material, such as metal materials, but not limited thereto. The drain electrode DOE2 may include any suitable transparent conductive material, such as indium tin oxide (ITO), but not limited thereto. As shown in FIG. 7, the electronic device ED2 may include the data lines DL2 and the scan lines GL2 disposed on the substrate SB. The disposition of the data lines DL2 and the scan lines GL2 may refer to the contents mentioned above, and will not be redundantly described. The gate electrode GE2 of the driving unit DU2 may be a portion of the scan line GL2, that is, the gate electrode GE2 is electrically connected to the scan line GL2; the source electrode SOE2 of the driving unit DU2 may be a portion of the data line DL2, that is, the source electrode SOE2 is electrically connected to the data line DL2. Therefore, the scan line GL2 may be formed of the conductive layer M5, and the data line DL2 may be formed of the conductive layer M6, but not limited thereto. The semiconductor layer SM2 may include a channel region CR2, a drain region DR2 and a source region SR2. The channel region CR2 may be defined as a portion of the semiconductor layer SM2 corresponding to (or overlapping) the scan line GL2. The source region SR2 of the semiconductor layer SM2 may be electrically connected to the data line DL2 or be electrically connected to the source electrode SOE2. The insulating layer IL7 of the circuit layer CL may serve as the gate insulating layer of the driving unit DU2. In some other embodiments, another metal layer (not shown) may be disposed on the conductive layer M7 and corresponding to the via VH1, that is, the another metal layer is located between the conductive layer M7 and the transparent conductive layer TCL, wherein the another metal layer may be used to reduce the risk of remaining of the light filtering layer CFL in the forming process of the via VH1.

In some embodiments, the conductive layer M4 in the circuit layer CL may be used as a light shielding layer, such as the above-mentioned light shielding layer LS. Specifically, the conductive layer M4 may be disposed corresponding to the driving unit DU2 or at least corresponding to the semiconductor layer SM2 of the driving unit DU2. In some embodiments, the conductive layer M4 may serve as another gate electrode of the driving unit DU2. In such condition, the driving unit DU2 may include a dual gate thin film transistor element. The conductive layer M4 may include any suitable conductive material, such as metal materials.

In addition, according to the present embodiment, the electronic device ED2 may not include the above-mentioned insulating layer IN, that is, the transparent conductive layer TCL may directly be disposed on the organic insulating layer OIL. In such condition, the transparent conductive layer TCL may directly contact the sidewall SW1 of the via VH1 and the sidewall SW2 of the via VH2. In the present embodiment, the via VH1 and the via VH2 may expose the drain electrode DOE2 of the driving unit DU2, and the transparent conductive layer TCL may directly contact the drain electrode DOE2 through the via VH1 and the via VH2 to be electrically connected to the driving unit DU2, but not limited thereto. The features of other elements or layers of the electronic device ED2 may refer to the contents of the above-mentioned embodiment, and will not be redundantly described.

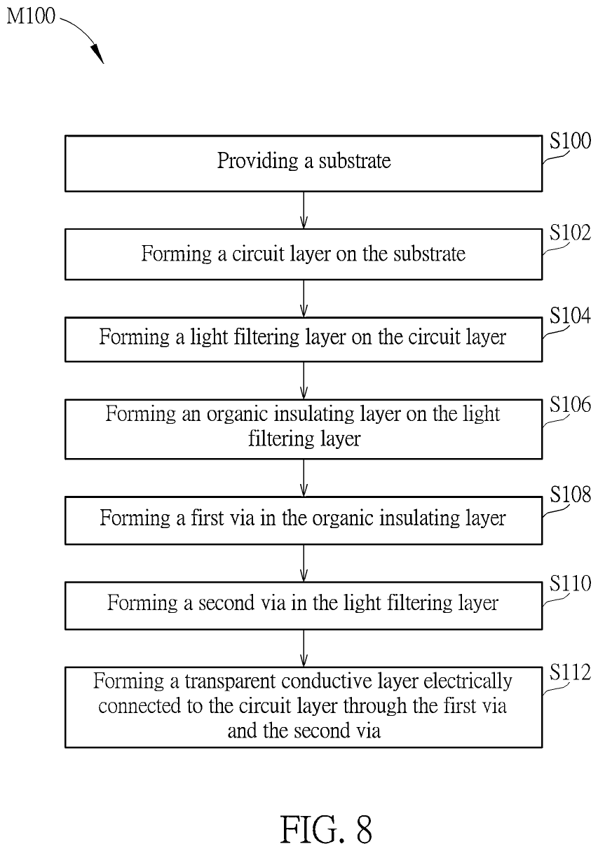

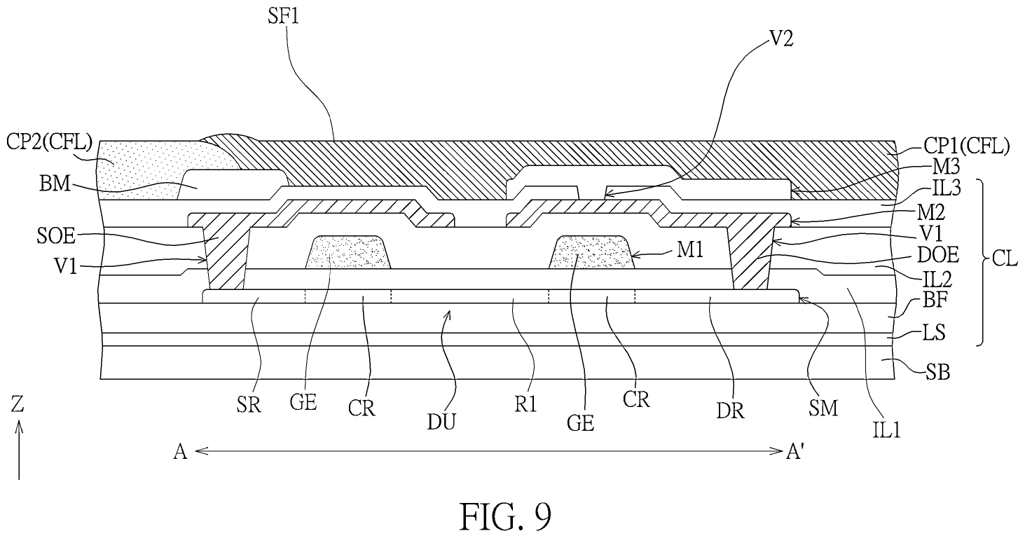

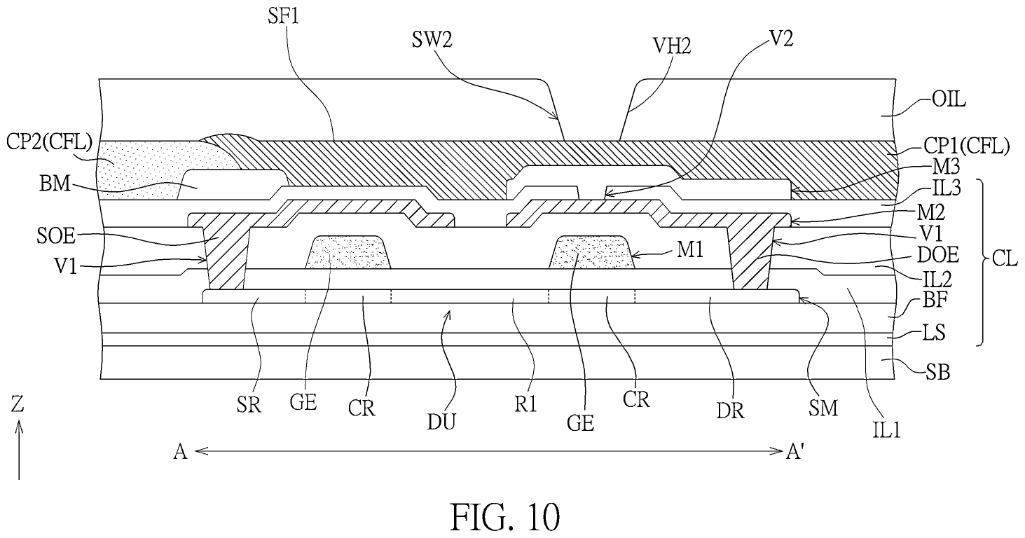

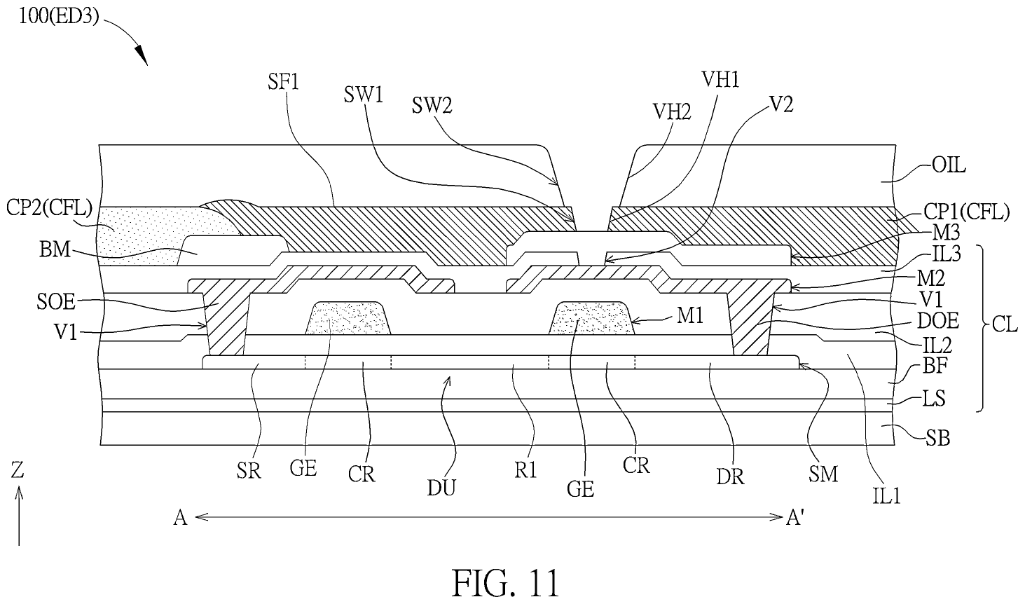

Referring to FIG. 8 to FIG. 11, FIG. 8 shows a flow chart of a manufacturing method of an electronic device according to a third embodiment of the present disclosure, and FIG. 9 to FIG. 11 schematically illustrate the manufacturing process of the electronic device according to the third embodiment of the present disclosure. According to the present embodiment, the manufacturing method M100 of an electronic device ED3 may include the following steps:
S100: providing a substrate;
S102: forming a circuit layer on the substrate;
S104: forming a light filtering layer on the circuit layer;
S106: forming an organic insulating layer on the light filtering layer;
S108: forming a first via in the organic insulating layer;
S110: forming a second via in the light filtering layer; and
S112: forming a transparent conductive layer electrically connected to the circuit layer through the first via and the second via.

The steps of the manufacturing method M100 of the electronic device ED3 will be detailed in the following.

As shown in FIG. 9, the manufacturing method M100 of the electronic device ED3 may include the step S100: providing a substrate SB at first and the step S102: forming a circuit layer CL on the substrate SB. The structure of the substrate SB may refer to the contents mentioned above, and will not be redundantly described. The structure of the circuit layer CL disposed on the substrate SB shown in FIG. 9 may be the structure of the circuit layer CL shown in FIG. 1, but not limited thereto. In other embodiments, the circuit layer CL having the structure shown in FIG. 6 or other suitable structures may be disposed on the substrate SB. Taking the structure shown in FIG. 9 as an example, the circuit layer CL may for example be formed by sequentially disposing the light shielding layer LS, the buffer layer BF, the semiconductor layer SM, the insulating layer IL1, the conductive layer M1, the insulating layer IL2, the conductive layer M2, the insulating layer IL3 and the conductive layer M3, but not limited thereto.

After the circuit layer CL is formed, the step S104 may be performed to form the light filtering layer CFL on the circuit layer CL. The light filtering layer CFL may for example be formed through a patterning process. The patterning process of the light filtering layer CFL for example includes a photolithography process, but not limited thereto. Specifically, the plurality of patterned first light filtering elements CP1, the plurality of patterned second light filtering elements CP2 and the plurality of patterned third light filtering elements CP3 may respectively be formed on the circuit layer CL through a photolithography process, thereby forming the light filtering layer CFL. The pattern design of the light filtering layer CFL may refer to the contents mentioned above, and will not be redundantly described. FIG. 9 exemplarily shows a portion of the first light filtering element CP1 and a portion of the second light filtering element CP2, and the third light filtering element CP3 is not shown in FIG. 9, but the present embodiment is not limited thereto.

After that, the step S106 may be performed to form the organic insulating layer OIL on the light filtering layer CFL, and then, the step S108 may be performed to form the first via in the organic insulating layer OIL. Specifically, as shown in FIG. 10, after the light filtering layer CFL is formed, an entire organic insulating layer OIL may be formed on the light filtering layer CFL at first. After that, a patterning process may be performed on the organic insulating layer OIL to remove a portion of the organic insulating layer OIL, thereby forming the via VH2 in the organic insulating layer OIL. In other words, the via VH2 is the first via described in the step S108. The disposition position of the via VH2 may correspond to the disposition position of the via VH1 formed in the subsequent process, or the disposition position of the via VH2 may correspond to the position of the conductive layer M3 electrically connected to the driving unit DU. The patterning process of the organic insulating layer OIL for example includes a photolithography process, but not limited thereto. After the via VH2 is formed, the via VH2 may include the sidewall SW2 corresponding to the side surface of the organic insulating layer OIL.

After that, the step S110 may be performed to form the second via in the light filtering layer CFL. Specifically, as shown in FIG. 11, after the via VH2 is formed, the portion of the light filtering layer CFL corresponding to the via VH2 may be removed to form the via VH1. In other words, the via VH1 is the second via described in the step S110. According to the present embodiment, the via VH1 in the light filtering layer CFL may be formed through an etching process, but not limited thereto. Specifically, after the via VH2 is formed, a photoresist layer (not shown in FIG. 11) may be formed on the organic insulating layer OIL, and the photoresist layer may be patterned to define the pattern of the via VH1. After that, an etching process may be performed on the light filtering layer CFL by taking the photoresist layer as the mask to form the via VH1. The photoresist layer for example includes positive type photoresist, but not limited thereto. After the via VH1 is formed, the via VH1 and the via VH2 may expose the conductive layer M3 electrically connected to the driving unit DU. Since the patterning ability of positive type photoresist is better than the patterning ability of the material of the light filtering element (such as color resist), the via VH1 with a lower size may be formed in the light filtering layer CFL. Therefore, the possibility of light leakage at the via VH1 may be reduced, thereby improving the display quality of the electronic device ED. It should be noted that FIG. 9 to FIG. 11 just show the manufacturing process of a group of the via VH1 and the via VH2, and other groups of the via VH1 and the via VH2 of the electronic device ED3 may be formed through the same process, which will not be redundantly described.

After the via VH1 is formed, the via VH1 may include the sidewall SW1 corresponding to the side surface of the light filtering layer CFL. According to the present embodiment, the via VH1 and the via VH2 may be formed through different processes, such that the size of the via VH1 may be less than the size of the via VH2. Specifically, the width of the via VH1 may be less than the width of the via VH2. Therefore, the sidewall SW1 of the via VH1 and the sidewall SW2 of the via VH2 may be discontinuous.

In some embodiments, there is no need to dispose the above-mentioned photoresist layer in the forming process of the via VH1. Specifically, after the via VH2 is formed in the organic insulating layer OIL, an etching process may be performed on the light filtering layer CFL by taking the organic insulating layer OIL as the mask to form the via VH1. In such condition, the organic insulating layer OIL may include any material suitable as the etching mask.

In some embodiments, the electronic device ED3 may further include the above-mentioned insulating layer IN. Specifically, after the via VH2 is formed in the organic insulating layer OIL, the insulating layer IN may be formed on the organic insulating layer OIL, wherein the insulating layer IN may enter the via VH2 and extend along the sidewall SW2 of the via VH2, and the insulating layer IN may cover the sidewall of the organic insulating layer OIL and the portion of the surface of the light filtering layer CFL exposed by the via VH2. In other words, the insulating layer IN may be disposed in the via VH2. In such condition, after the via VH2 is formed, the manufacturing method M100 of the electronic device ED3 may further include forming the insulating layer IN in the first via (that is, the via VH2). After that, the step S110 may be performed to form the second via (that is, the via VH1) in the light filtering layer CFL. Specifically, when an etching process is performed on the light filtering layer CFL, since the insulating layer IN may cover the portion of the surface of the light filtering layer CFL exposed by the via VH2, the etching process may also be performed on the insulating layer IN at the same time to form a via corresponding to the via VH1 in the insulating layer IN, such as the via VH3 shown in FIG. 1. In other words, the via VH1 and the via VH3 may be formed through the same etching process. In such condition, the manufacturing method M100 of the electronic device ED3 may further include forming a third via (that is, the via VH3) in the insulating layer IN, wherein the second via (that is, the via VH1) and the third via (that is, the via VH3) are formed simultaneously or formed in the same process. Since the insulating layer IN may cover the sidewall SW2 of the organic insulating layer OIL in the forming process of the via VH1, the possibility of damage to the organic insulating layer OIL may be reduced.

After the via VH1 is formed, the step S112 may be performed to form the transparent conductive layer TCL on the organic insulating layer OIL, wherein the transparent conductive layer TCL may be electrically connected to the circuit layer CL (or the driving unit DU in the circuit layer CL) through the first via (that is, the via VH2) and the second via (that is, the via VH1). For example, the transparent conductive layer TCL may extend along the sidewall SW2 of the via VH2 and the sidewall SW1 of the via VH1 and contact the conductive layer M3. In some embodiments, when the electronic device ED3 further includes the insulating layer IN, the insulating layer IN may be disposed between the sidewall SW2 of the via VH2 and the transparent conductive layer TCL, that is, the transparent conductive layer TCL may not contact the sidewall SW2. After the transparent conductive layer TCL is formed, the electronic device ED3 shown in FIG. 11 may be formed. It should be noted that the electronic device ED3 may further include other suitable elements or layers, and the manufacturing method M100 of the electronic device ED3 may include other suitable steps or processes according to the demands of the design of the electronic device ED3.

In some embodiments, the manufacturing method of the electronic device ED3 may include forming the via VH1 in the light filtering layer CFL at first, and then forming the via VH2 in the organic insulating layer OIL. Specifically, the step S100, the step S102 and the step S104 of the manufacturing method M100 may be performed at first, and after the step S104 (that is, forming the light filtering layer CFL on the circuit layer CL) is finished, the step S110 may be performed to form the via VH1 in the light filtering layer CFL. In some embodiments, the light filtering layer CFL may be patterned through a photolithography process, and the via VH1 may be formed in the patterning process of the light filtering layer CFL at the same time, that is, the via VH1 may be formed through the photolithography process. In some embodiments, the light filtering layer CFL may be patterned through a photolithography process at first, and then, the via VH1 may be formed through an etching process. After that, the step S106 may be performed to form the organic insulating layer OIL on the light filtering layer CFL, and the step S108 may be performed to form the via VH2 in the organic insulating layer OIL. After that, the step S112 may be performed to form the transparent conductive layer TCL on the organic insulating layer OIL, thereby forming the electronic device ED3.

In summary, an electronic device and a manufacturing method thereof are provided by the present disclosure. The electronic device includes the light filtering layer disposed on the circuit layer, the organic insulating layer disposed on the light filtering layer and the transparent conductive layer disposed on the organic insulating layer. The light filtering layer may have a first via having a first sidewall. The organic insulating layer may have a second via corresponding to the first via and having a second sidewall. According to the present disclosure, through the manufacturing method of the first via and the second via, the first sidewall of the first via and the second sidewall of the second via may be discontinuous, and the width of the first via may be less than the width of the second via. Therefore, the possibility of light leakage may be reduced, thereby improving the display quality of the electronic device.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a circuit layer disposed on the substrate;
a light filtering layer disposed on the circuit layer and having a first via;
an organic insulating layer disposed on the light filtering layer and having a second via, wherein the second via is corresponding to the first via; and
a transparent conductive layer electrically connected to the circuit layer through the first via and the second via,
wherein the first via has a first sidewall, the second via has a second sidewall, the first sidewall and the second sidewall are not continuous, and a width of the first via is less than a width of the second via.

2. The electronic device according to claim 1, wherein the second via exposes at least a portion of a top surface of the light filtering layer.

3. The electronic device according to claim 1, wherein the light filtering layer comprises a first light filtering element, a second light filtering element and a third light filtering element of different colors.

4. The electronic device according to claim 3, wherein the first via is formed in the first light filtering element, the second light filtering element and the third light filtering element.

5. The electronic device according to claim 3, wherein the light filtering layer has a plurality of the first vias respectively corresponding to the first light filtering element, the second light filtering element and the third light filtering element.

6. The electronic device according to claim 3, wherein the second via exposes a portion of the first light filtering element, a portion of the second light filtering element and a portion of the third light filtering element.

7. The electronic device according to claim 3, wherein the organic insulating layer has a plurality of the second vias respectively exposing the first light filtering element, the second light filtering element and the third light filtering element.

8. The electronic device according to claim 1, further comprising an insulating layer disposed in the second via and disposed on the light filtering layer.

9. The electronic device according to claim 8, wherein the insulating layer contacts the second sidewall and contacts a top surface of the light filtering layer.

10. The electronic device according to claim 8, wherein the insulating layer has a third via corresponding to the first via and the second via.

11. The electronic device according to claim 10, wherein the transparent conductive layer directly contacts the first sidewall and a third sidewall of the third via.

12. The electronic device according to claim 1, wherein the first sidewall and the second sidewall form a staircase-shaped sidewall.

13. The electronic device according to claim 1, wherein the transparent conductive layer directly contacts the first sidewall and the second sidewall.

14. A manufacturing method of an electronic device, comprising:
providing a substrate;
forming a circuit layer on the substrate;
forming a light filtering layer on the circuit layer;
forming an organic insulating layer on the light filtering layer;
forming a first via in the organic insulating layer;
forming a second via in the light filtering layer, wherein the second via is corresponding to the first via; and
forming a transparent conductive layer electrically connected to the circuit layer through the first via and the second via,
wherein the first via has a first sidewall, the second via has a second sidewall, the first sidewall and the second sidewall are not continuous, and a width of the second via is less than a width of the first via.

15. The manufacturing method according to claim 14, wherein the transparent conductive layer directly contacts the first sidewall and the second sidewall.

16. The manufacturing method according to claim 14, further comprising forming an insulating layer in the first via after the first via is formed.

17. The manufacturing method according to claim 16, wherein the insulating layer contacts the first sidewall and contacts a top surface of the light filtering layer.

18. The manufacturing method according to claim 16, further comprising forming a third via in the insulating layer, wherein the second via and the third via are formed simultaneously.

19. The manufacturing method according to claim 18, wherein the transparent conductive layer directly contacts the second sidewall and a third sidewall of the third via after the transparent conductive layer is formed.

20. The manufacturing method according to claim 14, wherein the second via is formed through an etching process.
